(19) United States
(12) Patent Application Publication
(10) Pub. No.: US 2008/0070155 A1
(43) Pub. Date: Mar. 20, 2008

(54) INCLUSION COMPLEX, PHOTORESIST COMPOSITION HAVING THE INCLUSION COMPLEX AND METHOD OF FORMING A PATTERN USING THE PHOTORESIST COMPOSITION

(75) Inventors: Hyo-Jin YUN, Anyang-si (KR); Young-Gil KWON, Yongin-si (KR); Jae-Ho KIM, Yongin-si (KR); Boo-Deuk KIM, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/853,075

(22) Filed: Sep. 11, 2007

(30) Foreign Application Priority Data
Sep. 14, 2006 (KR) 2006-88826

(51) Int. Cl. G03F 7/031; C08B 37/16

(52) U.S. Cl. 430/270.1; 430/323; 536/103

(57) ABSTRACT

A photoresist is formed on an object layer of a semiconductor device by coating the object layer with a photoresist composition including about 7 percent to about 14 percent by weight of an inclusion complex having a β-cyclodextrin derivative as a host and an adamantane derivative as a guest, about 0.1 percent to about 0.5 percent by weight of a photoacid generator, and a remainder of an organic solvent.

### CROSS-REFERENCE TO PRIORITY APPLICATION

A claim of priority is made to Korean Patent Application No. 10-2006-0088826, filed on Sep. 14, 2006, the subject mater of which is hereby incorporated by reference.

### CROSS-REFERENCE TO RELATED APPLICATION

This application is related to co-pending U.S. patent application to Hyo-Jin YUN et al., entitled “Cyclodextrin Derivative, Photoresist Composition Including the Cyclodextrin Derivative and Method of Forming a Pattern Using the Photoresist Composition” (Attorney Docket No. SEC.2082), which claims priority of Korean Patent Application No. 10-2006-0088827 (filed on Sep. 14, 2006), the subject mater of which is hereby incorporated by reference.

### BACKGROUND OF THE INVENTION

1. Field of the Invention

The present invention relates to forming a pattern using a photoresist composition including an inclusion complex. More particularly, example embodiments of the present invention relate to an inclusion complex, a photoresist composition having the inclusion complex and a method of forming a pattern using the photoresist composition.

2. Description of the Related Art

Recently, semiconductor device technology has rapidly advanced, as information media, such as personal computers, have become more widely used. Semiconductor devices are required to operate at very high speeds and to have large storage capacities. To meet recent industry trends, the manufacturing technologies of semiconductor devices have been developed to improve integration, reliability and response speeds of the semiconductor devices. In particular, a fine processing technology, such as photolithography, has enabled stricter requirements to be met, improving the degree of integration of semiconductor devices.

To fabricate a semiconductor device, a chemical amplification type photoresist composition is used in the photolithography process in order to form a photoresist pattern utilized as an etching mask. The photoresist composition is prepared by mixing a photoacid generator for generating an acid material, a polymer for sensitively reacting with the acid material, and a solvent. The photoresist composition has a variable solubility in a developing solution, which is changed in accordance with a light exposure operation. Accordingly, the photoresist pattern having a determined shape may be acquired by coating a surface of a substrate with the photoresist composition, partially exposing a photoresist film to light, and sequentially developing the exposed portions of the photoresist film.

A photoresist composition, including a polymer having a high molecular weight, has been conventionally used for forming a photoresist pattern. As a pattern in a semiconductor device becomes finer, a line width of the photoresist pattern is reduced to a molecular size of the polymer. The polymer has various molecular weights and various sizes, as well as an entangled structure. When a photoresist composition including the polymer is developed, molecules of the polymer are swollen in a developing solution, and are not dissolved in the developing solution at a constant rate. Thus, a resolution of the photoresist pattern is reduced and a line width roughness of the photoresist pattern deteriorates.

When a semiconductor device has a 240 nm dimension, a deviation of the line width roughness in a photoresist pattern is at most about 20 nm, which is about 16 percent of a line width based on both edges of the line. Thus, the deviation of the line width is inevitably generated in the method for fabricating a semiconductor device. However, as a semiconductor device having a 90 nm dimension is developed, the deviation of the line width roughness is increased to about 22 percent of the line width. When a semiconductor device has a dimension less than about 70 nm, the deviation of the line width roughness is increased to more than about 29 percent.

In order to improve the photoresist composition, a molecular weight of a polymer included in a photoresist composition has been adjusted or a type of a de-blocking group of the polymer has been changed. However, photoresist compositions having an adjusted molecular weight or a changed de-blocking group still result in great loss of a photoresist pattern in a developing process and a deterioration of mechanical properties of the polymer included in the photoresist composition. This is because a molecular size of the polymer applied to the photoresist composition is not considered.

### SUMMARY OF THE INVENTION

An aspect of the present invention provides an inclusion complex for a photoresist including a β-cyclodextrin derivative as a host and an adamantane derivative as a guest. The inclusion complex may have a chemical structure represented by Formula (1), in which R₁ represents an alkyl group having 1 to 10 carbon atoms, and X represents a carboxyl group or an alkyl group having 1 to 4 carbon atoms:

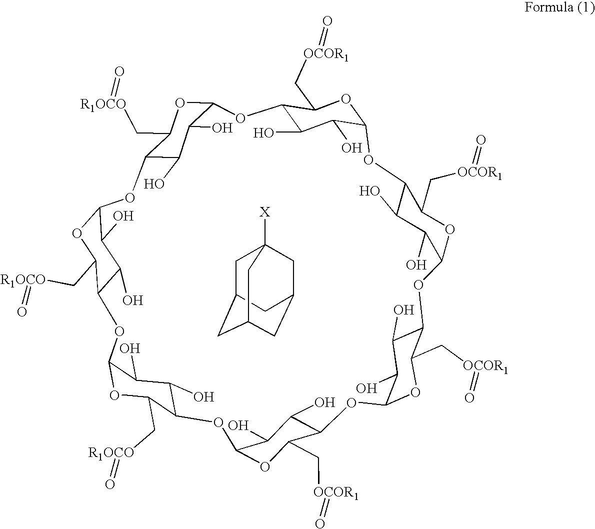

The β-cyclodextrin derivative may be prepared by combining β-cyclodextrin with a tert-butyl carbonate and represented by Formula (2):

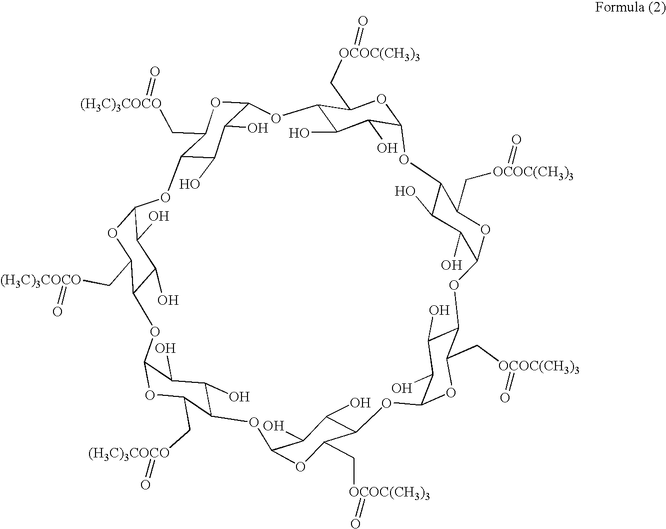

The adamantane derivative may have a chemical structure represented by formula (3), in which X represents a carboxyl group or an alkyl group having 1 to 4 carbon atoms:

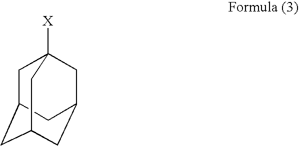

The inclusion complex may be prepared by inserting the adamantane derivative into a cavity of β-cyclodextrin and by reacting β-cyclodextrin with a dialkyl dicarbonate.

Another aspect of the present invention provides a photoresist composition including about 7 percent to about 14 percent by weight of an inclusion complex having a β-cyclodextrin derivative as a host and an adamantane derivative as a guest, about 0.1 percent to about 0.5 percent by weight of a photoacid generator, and a remainder of an organic solvent.

The inclusion complex may have a chemical structure represented by Formula (1). The β-cyclodextrin derivative may be prepared by combining β-cyclodextrin with a tert-butyl carbonate. Also, the β-cyclodextrin derivative may be represented by Formula (2) and the adamantane derivative may be represented by Formula (3).

The photoacid generator may include at least one selected from the group consisting of a triarylsulfonium salt, a diaryliodonium salt, a sulfonate and N-hydroxysuccinimide triflate. The organic solvent may include at least one selected from the group consisting of ethylene glycol monomethyl ether, ethylene glycol monoethyl ether, propylene glycol methyl ether, methyl cellosolve acetate, ethyl cellosolve acetate, diethylene glycol monomethyl ether, diethylene glycol monoethyl ether, propylene glycol methyl ether acetate, propylene glycol propylether acetate, diethylene glycol dimethylether, ethyl lactate, toluene, xylene, methyl ethyl ketone, cyclohexanone, 2-heptanone, 3-heptanone and 4-heptanone.

Yet another embodiment of the present invention provides a method of forming a pattern. In the method of forming the pattern, a photoresist film is formed on an object layer by coating the object layer with a photoresist composition, which includes about 7 percent to about 14 percent by weight of an inclusion complex having a chemical structure represented by Formula (1), in which R₁ represents an alkyl group having 1 to 10 carbon atoms, and X represents a carboxyl group or an alkyl group having 1 to 4 carbon atoms. The photoresist composition further includes about 0.1 percent to about 0.5 percent by weight of a photoacid generator, and an organic solvent, which may be the remainder percentage by weight. The photoresist film is partially exposed to light by performing an exposure process. The photoresist film is developed using a developing solution to form a photoresist pattern on the object layer. The object layer is partially etched using the photoresist pattern as an etching mask to form the pattern on the substrate.

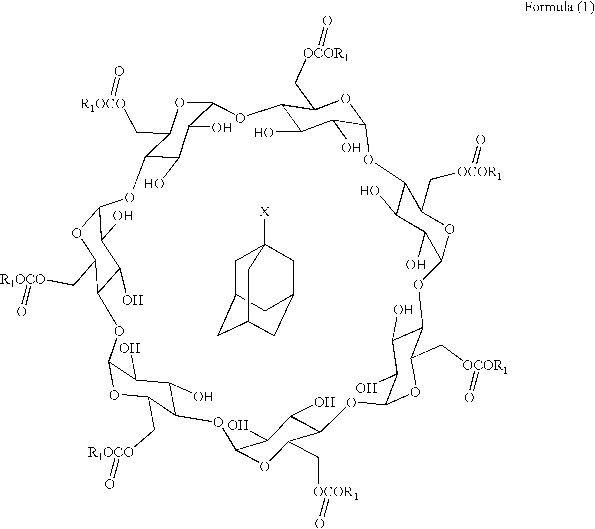

According to exemplary embodiments of the present invention, the inclusion complex may have an excellent solubility to a developing solution to form a photoresist composition having a uniform profile. The photoresist composition may include a compound having a low molecular weight as a building block instead of a polymer, may have an enhanced solubility and may form a photoresist pattern having a uniform profile. In addition, the photoresist composition includes the inclusion complex having a toroidal structure, so that the photoresist composition may have advantages of a generally used photoresist composition and an enhanced etching resistance. Accordingly, a photoresist pattern formed using the photoresist composition may have an improved etching resistance in a process of etching an underlying layer of the photoresist pattern, for example, as compared to a photoresist composition including a molecular resin. Also, a pattern having a good profile may be formed.

### BRIEF DESCRIPTION OF THE DRAWINGS

The embodiments of the present invention will be described with reference to the attached drawings, in which:

FIGS. 1 to 4 are cross-sectional views illustrating a method of forming a pattern in accordance with an exemplary embodiment of the present invention.

### DETAILED DESCRIPTION OF THE EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third, etc., may be used to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

Spatially relative terms, such as “beneath,” “below,” “lower,” “above,” “upper” and the like, may be used for ease of description to describe the relationships between elements or features, as illustrated in the figures. It is understood that the spatially relative terms are intended to encompass different orientations of the device in use or operation, in addition to the orientation depicted in the figures. For example, when the device in the figures is turned over, elements described as “below” or “beneath” other elements or features would then be oriented above the other elements or features. Thus, the example term “below” can encompass both an orientation of above and below. The device may be otherwise oriented (rotated 90 degrees or at other orientations) and the spatially relative descriptors are to be interpreted accordingly.

The terminology used herein is for the purpose of describing particular embodiments only, and is not intended to be limiting of the present invention. As used herein, the singular forms “a,” “an” and “the” are intended to include the plural forms as well, unless the context clearly indicates otherwise. It is further understood that the terms “comprises” and/or “comprising” specify the presence of stated features, integers, steps, operations, elements and/or components, but do not preclude the presence of one or more additional features, integers, steps, operations, elements, components and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated in the figures, but are to include deviations in shapes that result, for example, from manufacturing. For example, an implanted region illustrated as a rectangle for purposes of description, may typically have rounded or curved features and/or a gradient of implant concentration at its edges, as a practical matter, rather than a binary change from implanted to non-implanted regions. Likewise, a buried region formed by implantation may result in some implantation in a region between the buried region and the surface through which the implantation takes place. Thus, the regions illustrated in the figures are schematic in nature and their shapes are not intended to illustrate the actual shape of a region of a device, and are not intended to otherwise limit the scope of the present invention.

Unless otherwise defined, all terms (including technical and scientific terms) used herein have the same meaning as commonly understood by one of ordinary skill in the art. It is further understood that terms, such as those defined in commonly used dictionaries, should be interpreted as having meanings that are consistent with their respective meanings in the context of the relevant art and will not be interpreted in an idealized or overly formal sense, unless expressly so defined herein.

Inclusion Complex

An inclusion complex for a photoresist of the present invention includes a host molecule and a guest molecule. The host molecule includes a β-cyclodextrin derivative having an adhesion group. The guest molecule includes an adamantane derivative as an etching resistance group. In accordance with an exemplary embodiment of the present invention, the β-cyclodextrin derivative may include β-cyclodextrin and β-cyclodextrin to which a protecting group is bound. The inclusion complex may have the following characteristics.

First, the inclusion complex has a single molecular weight and a definite molecular structure, and thus there is no distribution of the molecular weight. Second, a building block of a photoresist pattern is a single molecule, so that the corresponding photoresist pattern may have a molecular level resolution. Third, the inclusion complex included in a photoresist film may provide a large solubility difference between a light-exposed portion and an unexposed portion on the photoresist film in a developing process, so that the photoresist film may be uniformly developed. A molecular interaction, such as a chain entanglement, may not be generated because the inclusion complex has a small molecular size, a short rotational radius and a complex three-dimensional structure. Fourth, because there is no chain entanglement, a line width roughness of the photoresist pattern may be greatly reduced. Fifth, the adamantane derivative included in the inclusion complex may function as an etching resistance group during an etching process, so that the inclusion complex may provide an enhanced-plasma etching resistance

The inclusion complex having such characteristics includes a β-cyclodextrin derivative as a host and an adamantane derivative as a guest. The inclusion complex has a chemical structure represented by Formula (1):

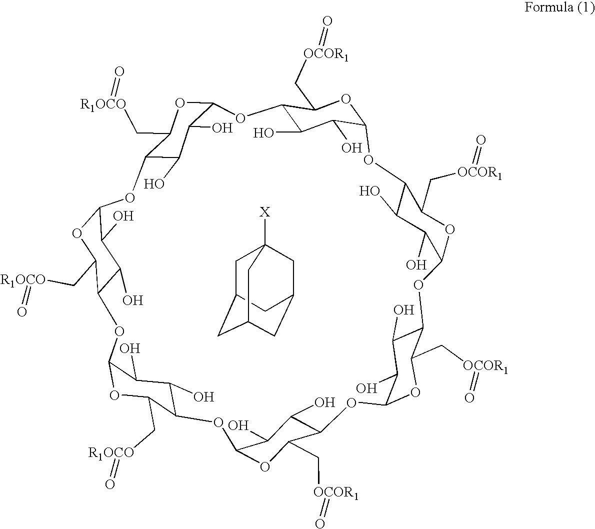

In Formula (1), R₁ represents an alkyl group having 1 to 10 carbon atoms, and X represents a carboxyl group or an alkyl group having 1 to 4 carbon atoms. In an exemplary embodiment, R₁ may be tert-butyl group, and X in the Formula (1) may be a carboxyl group.

In accordance with an exemplary embodiment of the present invention, the inclusion complex may be represented by Formula (1-1):

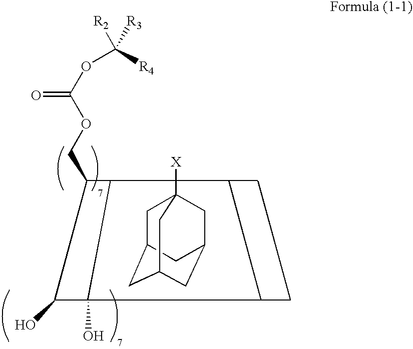

In Formula (1-1), each of R₂, R₃ and R₄ is independently an alkyl group having 1 to 4 carbon atoms or a hydroxyl group, and X is a carboxyl group or an alkyl group having 1 to 4 carbon atoms. In an exemplary embodiment, each of the R₂, R₃ and R₄ may be a methyl group, and the X may be a carboxyl group

In accordance with an exemplary embodiment of the present invention, the inclusion complex may be prepared by inserting an adamantine derivative represented by Formula (3) into a cavity of β-cyclodextrin derivative represented by Formula (2):

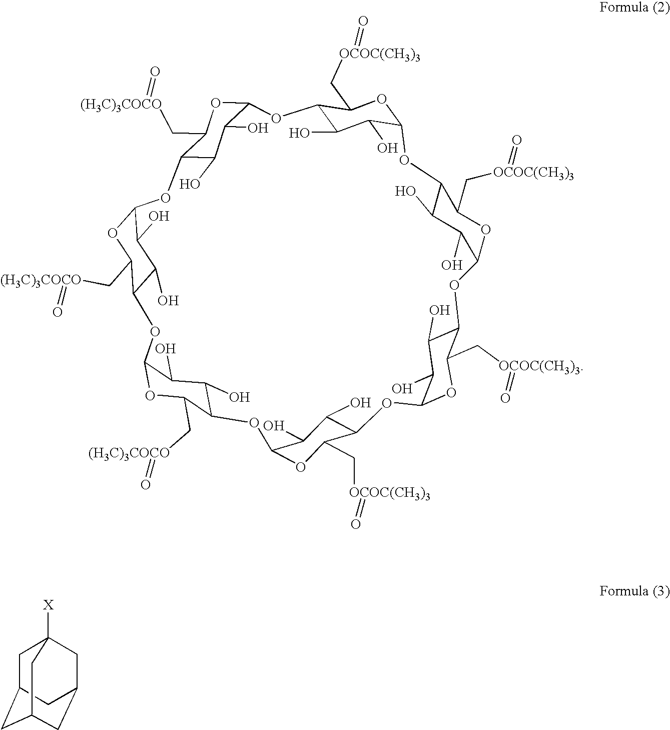

In formula (3), X represents a carboxyl group or an alkyl group having 1 to 4 carbon atoms. A β-cyclodextrin derivative may be applied to an exemplary embodiment, and may have a chemical structure represented by Formula (4):

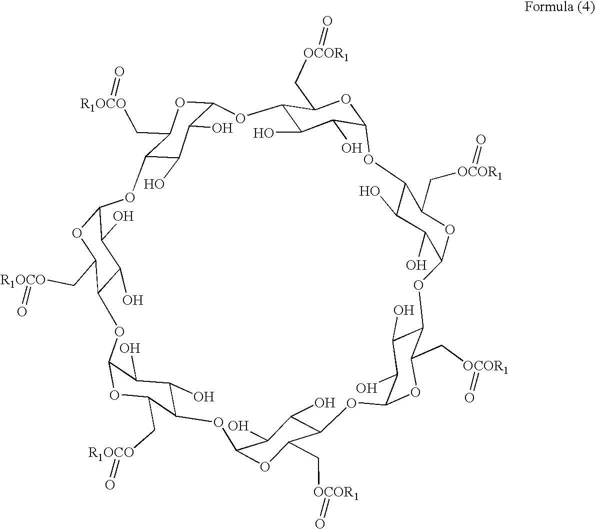

In Formula (4), R₁ represents an alkyl group having 1 to 10 carbon atoms. In accordance with an exemplary embodiment of the present invention, the β-cyclodextrin derivative may be prepared by combining β-cyclodextrin with a tert-butyl carbonate group, and may be represented by Formula (2).

The β-cyclodextrin derivative represented by the Formula (4) has a chemical structure including β-cyclodextrin and an alkyl carbonate group. The β-cyclodextrin derivative has a three-dimensional toroidal structure with openings. In the β-cyclodextrin derivative, an inner portion of the toroid has a hydrophobic carbon chain and an outer portion of the toroid has a hydrophilic alkyl carbonate substitute. The adamantane derivative has a hydrophobic property, and thus the adamantane derivative can be easily introduced into the hydrophobic cavity of the β-cyclodextrin derivative. For example, it may be an interaction binding energy that allows the hydrophobic adamantane derivative into the cavity of the β-cyclodextrin derivative. Examples of the interaction binding energy may include hydrogen bonding energy, electrostatic interaction energy, van der Waals force, molecular binding energy, etc.

In accordance with an exemplary embodiment of the present invention, the inclusion complex may be prepared by inserting the adamantane derivative represented by Formula (3) into β-cyclodextrin represented by Formula (5), and by reacting the β-cyclodextrin having the adamantane derivative in its cavity with an alkyl carbonate represented by Formula (6), in which, R₁ represents an alkyl group having 1 to 4 carbon atoms.

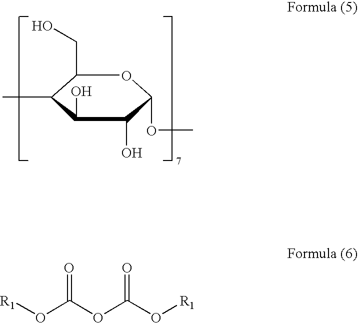

Particularly, the inclusion complex has β-cyclodextrin represented by Formula (5) as a host molecule. The β-cyclodextrin represented by Formula (5) has an inner cavity that may contain a guest molecule, such as the adamantane derivative represented by Formula (3). Additionally, the β-cyclodextrin has a hydrophobic carbon chain in its inner portion and a hydrophilic hydroxyl group in its outer portion. Therefore, the hydrophobic adamantane derivative may be easily inserted into the hydrophobic cavity of the β-cyclodextrin. An interaction binding energy may allow the hydrophobic adamantane derivative into the cavity of the β-cyclodextrin derivative.

After inserting the adamantane derivative into the cavity of the β-cyclodextrin, the β-cyclodextrin may be reacted with a dialkyl dicarbonate to complete the inclusion complex. The reaction between the β-cyclodextrin and the dialkyl dicarbonate may occur in an organic solvent. For example, di-tert-butyl dicarbonate represented by Formula (7) may be reacted with the β-cyclodextrin, including the adamantane derivative, so that a hydroxyl group of the β-cyclodextrin may be substituted by a tert-butyl carbonate group. As a result, the inclusion complex may be obtained.

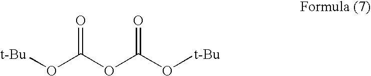

The alkyl carbonate group binding to the β-cyclodextrin may function as a protecting group. The protecting group may be detached from the β-cyclodextrin by reacting with acid (H⁺), while being provided with some energy. Examples of the alkyl carbonate group may include a methyl carbonate group, an ethyl carbonate group, a propyl carbonate group, a butyl carbonate group, a pentyl carbonate group, a hexyl carbonate group, a heptyl carbonate group, an octyl carbonate group, a nonyl carbonate group, a decyl carbonate group, etc., which can be used alone or in any mixture thereof. In addition, examples of the organic solvent may include N,N-dimethylacetamide, diethylacetamide, N,N-dimethylpropionamide, etc., which can be used alone or in any mixture thereof.

The inclusion complex having the chemical structure described above may be applied to a photoresist composition to form a photoresist pattern having a fine line width and an improved roughness. Furthermore, the inclusion complex may improve an etching resistance of a photoresist pattern formed using the inclusion complex.

Photoresist Composition

A photoresist composition of the present invention includes the above-described inclusion complex, having a β-cyclodextrin derivative as a host and an adamantane derivative as a guest, a photoacid generator and an organic solvent.

In accordance with an exemplary embodiment of the present invention, the inclusion complex has a chemical structure represented by Formula (1), in which R₁ represents an alkyl group having 1 to 10 carbon atoms, and X represents a carboxyl group or an alkyl group having 1 to 4 carbon atoms:

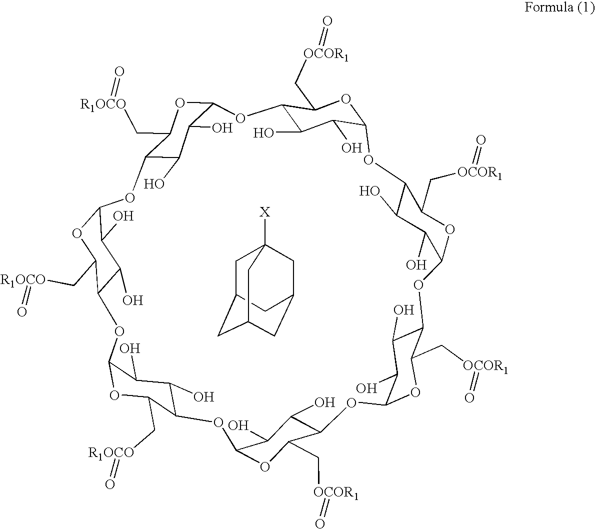

When the photoresist composition includes less than about 7 percent by weight of the inclusion complex, based on a total weight of the photoresist composition, the photoresist pattern may have a poor etching resistance, so that the photoresist pattern may not be used as an etching mask. In addition, when the amount of the inclusion complex is greater than about 14 percent by weight, it may be difficult to form a photoresist film having a substantially uniform thickness on an object layer. Therefore, the photoresist composition may include about 7 percent to about 14 percent by weight of the inclusion complex. For example, when the photoresist composition is applied to form a photoresist pattern having a line width less than about 80 nm, the photoresist composition may include about 9 percent to about 12 percent by weight of the inclusion complex.

The inclusion complex represented by Formula (1) may include a host molecule and a guest molecule. The host molecule includes the β-cyclodextrin derivative having an adhesion group. The guest molecule includes the adamantane derivative as an etching resistance group. In accordance with an exemplary embodiment of the present invention, the β-cyclodextrin derivative may include β-cyclodextrin and a β-cyclodextrin derivative having a protecting group.

The photoresist composition includes the inclusion complex as a building block, which has the β-cyclodextrin derivative having a toroidal structure as a host and the adamantane derivative having an etching resistance as a guest. Therefore, an etching resistance of a photoresist pattern formed using the photoresist composition may be improved. Additionally, due to the toroidal structure of the β-cyclodextrin derivative, the inclusion complex may not exhibit crystalline properties that are generally characteristic of a low molecular weight compound, and may have amorphous properties. The inclusion complex having amorphousness may be applied to a photoresist composition suitable for spin-coating. The inclusion complex represented by Formula (1) has been previously described, so any further explanation in this regard will not be repeated herein.

In the photoresist composition according to an exemplary embodiment of the present invention, a certain quantity of an acid (H⁺) and heat may be required to detach the protecting group from the inclusion complex represented by Formula (1). The acid may be generated from a photoacid generator included in the photoresist composition. The photoacid generator is a material that may generate an acid when receiving light.

When the photoresist composition has less than about 0.1 percent by weight of the photoacid generator based on a total weight of the photoresist composition, the acid (H⁺) may not be sufficiently generated. Therefore, an ability to detach the protecting group from the inclusion complex may be deteriorated in an exposure process. In addition, when the amount of the photoacid generator is greater than about 0.5 percent by weight, the acid may be overproduced in the exposure process, and thus a photoresist film may be excessively developed and/or a top loss of a photoresist pattern may be generated while performing a developing process. Therefore, the photoresist composition may include about 0.1 to about 0.5 percent by weight of the photoacid generator, and preferably about 0.2 percent to about 0.4 percent by weight of the photoacid generator.

Examples of the photoacid generator that may be applied to the photoresist composition may include a triarylsulfonium salt, a diaryliodonium salt, a sulfonate, N-hydroxysuccinimide triflate, etc., which may be used alone or in any mixture thereof.

Examples of the photoacid generator may include triphenylsulfonium triflate, triphenylsulfonium antimony salt, diphenyliodonlum triflate, diphenyliodonium antimony salt, methoxydiphenyliodonium triflate, di-tert-butyldiphenyliodonium triflate, 2,6-dinitrobenzyl sulfonate, pyrogallol tris(alkylsulfonate), norbornene dicarboximide triflate, triphenylsulfonium nonaflate, diphenyliodonium nonaflate, methoxydiphenyliodonium nonaflate, di-tert-butyldiphenyliodonium nonaflate, N-hydroxysuccinimide nonaflate, norbornene dicarboximide nonaflate, triphenylsulfonium perfluorooctanesulfonate, diphenyliodonium perfluorooctanesulfonate, methoxyphenyliodonium perfluorooctanesulfonate, di-tert-butyldiphenyliodonium triflate, N-hydroxysuccinimide perfluorooctanesulfonate, norbornene dicarboximide perfluorooctanesulfonate, etc., which may be used alone or in any mixture thereof.

Examples of the organic solvent that may be used in the photoresist composition may include ethylene glycol monomethyl ether, ethylene glycol monoethyl ether, propylene glycol methyl ether, methyl cellosolve acetate, ethyl cellosolve acetate, diethylene glycol monomethyl ether, diethylene glycol monoethyl ether, propylene glycol methylether acetate, propylene glycol propylether acetate, diethylene glycol dimethyl ether, ethyl lactate, toluene, xylene, methyl ethyl ketone, cyclohexanone, 2-heptanone, 3-heptanone, 4-heptanone, etc., which may be used alone or in any mixture thereof.

In an exemplary embodiment, the photoresist composition may further include an additive in order to improve characteristics of a photoresist. Examples of the addictive may include an organic base and a surfactant.

The organic base may prevent an airborne alkali compound, such as an amine, from influencing a photoresist pattern obtained after the exposure process. Thus the organic base may maintain or adjust a shape of a photoresist pattern. Examples of the organic base that may be used in the photoresist composition may include triethylamine, triisobutylamine, triisooctylamine, triisodecylamine, diethanolamine, triethanolamine etc., which may be used alone or in any mixture thereof.

The surfactant may improve a coatability of the photoresist composition and inhibit a striation on a photoresist film formed using the photoresist composition. Examples of the surfactant that may be used in the photoresist composition may include fluorine-containing surfactants, such as those available under the trade names SURFLON SC-103, SR-100 (manufactured by Asahi Glass Co., Ltd.), EF-361 (manufactured by Tohoku Hiryou K.K.), FLORAD Fc-431, Fc-135, Fc-98 and Fc-176 (manufactured by Sumitomo 3M Ltd.), etc. These exemplary surfactants are commercially available.

Method of Forming a Pattern

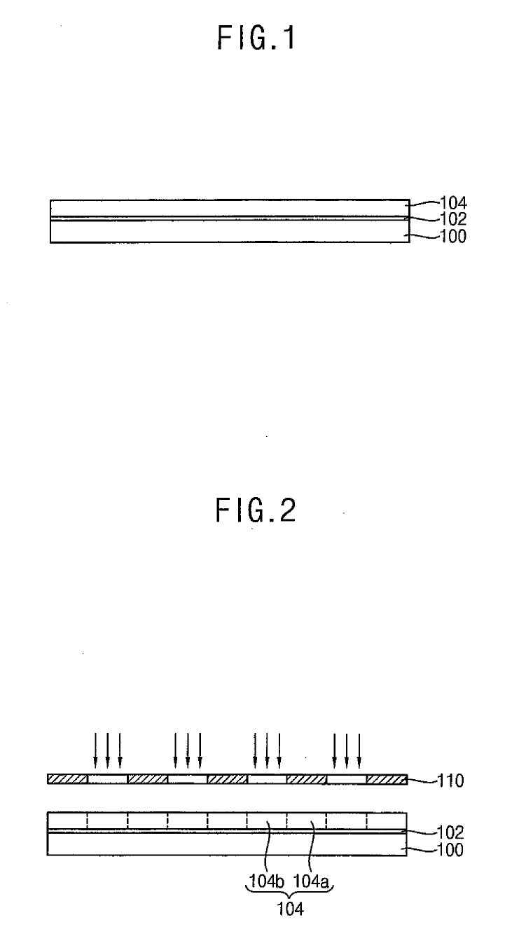

FIGS. 1 to 4 are cross-sectional views illustrating a method of forming a pattern, in accordance with an exemplary embodiment of the present invention.

Referring to FIG. 1, an etching object is prepared. The etching object may be, for example, a semiconductor substrate 100 and a thin film 102 formed on a semiconductor substrate. An exemplary case in which the etching object includes a thin film 102 will be described hereinafter. Examples of the thin film 102 may include a silicon nitride film, a polysilicon film, a silicon oxide film, etc.

After rinsing the surface of the thin film 102 to remove contaminants from the thin film 102, a photoresist film 104 is formed on the thin film 102 (e.g., an object layer) by coating the thin film 102 with a photoresist composition including an inclusion complex that has a chemical structure represented by Formula (1), a photoacid generator and an organic solvent.

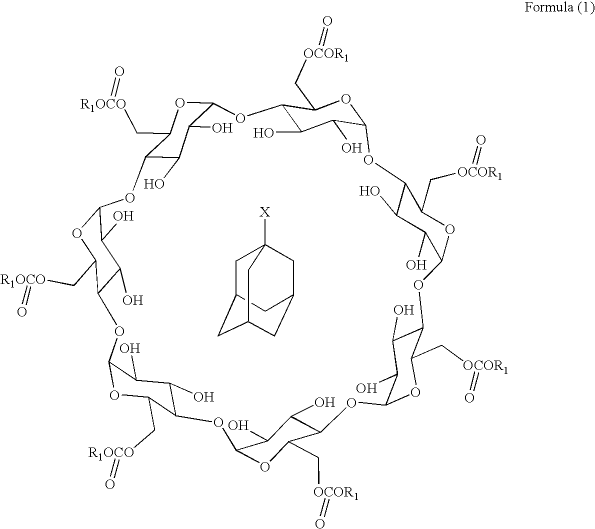

In Formula (1), R₁ represents an alkyl group having 1 to 10 carbon atoms, and X represents a carboxyl group or an alkyl group having 1 to 4 carbon atoms. The inclusion complex represented by Formula (1) and the photoresist composition including the inclusion complex have been previously described, so any further explanations will not be repeated herein for brevity.

The semiconductor substrate 100 on which the photoresist film 104 is formed may be thermally treated in a first baking process. The first baking process may be performed, for example, at a temperature of about 90° C. to about 120° C. In the first baking process, adhesiveness between the photoresist film 104 and the thin film 102 may be enhanced.

Referring to FIG. 2, the photoresist film 104 is partially exposed to light during an exposure process, according to an exemplary embodiment of the present invention. In particular, a mask 110 having a predetermined pattern may be positioned on a mask stage of an exposure apparatus, and then the mask 110 is aligned over the photoresist film 104. A portion of the photoresist film 104 formed on the substrate 100 may be selectively reacted with light transmitted through the mask 110, while the light is irradiated on the mask 110 for a predetermined time. Examples of the light that may be used in the exposure process may include an ArF laser having a wavelength of about 193 nm, a KrF laser having a wavelength of about 248 nm, an F₂ laser, an Hg—Xe light, etc.

An exposed portion 104b of the photoresist film 104 may be more hydrophilic than an unexposed portion 104a of the photoresist film 104. Accordingly, the exposed portion 104b and the unexposed portion 104a of the photoresist film 104 may have different solubilities.

Subsequently, a second baking process may be performed on the semiconductor substrate 100. The second baking process may be performed, for example, at a temperature of about 90° C. to about 150° C. During the second baking process, the exposed portion 104b of the photoresist film 104 may become soluble in a developing solution.

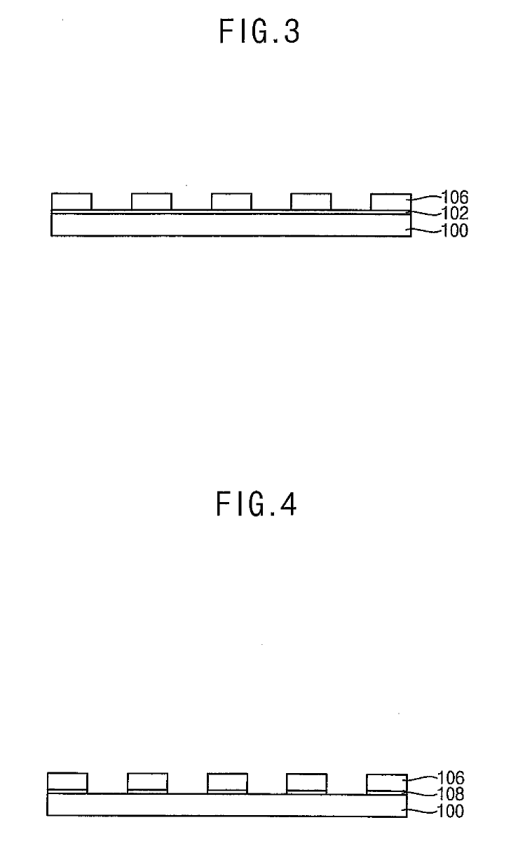

Referring to FIG. 3, a photoresist pattern 106 is formed by dissolving the exposed portion 104b of the photoresist film 104 in a developing solution and then removing the exposed portion 104b from the photoresist film 104.

Particularly, the exposed portion 104b of the photoresist film 104 may be removed by dissolving the exposed portion 104b of the photoresist film 104 using an aqueous solution of tetramethylammonium hydroxide, for example, as the developing solution. The hydrophilicities in the unexposed and exposed portions 104a and 104b of the photoresist film 104, respectively, are different from each other, and thus the exposed portion 104b of the photoresist film 104 may be easily removed by being dissolved in the developing solution, to provide the photoresist pattern 106. Subsequently, the semiconductor substrate 100 having the photoresist pattern 106 may be rinsed and dried to complete the photoresist pattern 106.

The photoresist composition includes the inclusion complex having a molecular weight less than or equal to about 1,850. Accordingly, a deviation of line width roughness in the photoresist pattern 106 may be less than or equal to about 14 percent, based on both edges of a line.

Referring FIG. 4, the thin film 102 on the substrate 100 is partially etched using the photoresist pattern 106 as an etching mask to form a thin film pattern 108 on the substrate. The photoresist pattern 106 includes the adamantane derivatives that may function as an etching resistance group, so that the photoresist pattern 106 may have an improved etching resistance.

The present invention will be described in detail through examples of preparing an inclusion complex and a photoresist composition having the inclusion complex, set forth below. The present invention may, however, be embodied in many different forms and should not be construed as limited to examples herein.

### EXAMPLE 1

### Synthesis of an Inclusion Complex

About 14.8 g, i.e., 0.013 moles, of β-cyclodextrin and an excess of 1-adamantanecarboxylic acid were dissolved in about 800 mL of water, and then the solution was stirred at a temperature of about 60° C. for about twenty-four hours. Thereafter, water was evaporated from the solution and a solid material was obtained. The obtained solid material was washed with chloroform to remove residue of the 1-adamantanecrboxylic acid. After the solid material was dried at a temperature of about 50° C. under a vacuum condition for twelve hours, a first product was obtained. The first product, i.e., a white solid material, was β-cyclodextrin, including 1-adamantanecarboxylic acid in its cavity.

About 13.15 g, i.e., 0.010 moles, of the first product and 4-(dimethylamino)pyridine were dissolved in about 20 mL of N,N-dimetylacetamide in an ice bath. About 17.46 g, i.e., 18.28 mL or 0.080 moles, of di-tert-butyl dicarbonate were slowly added to the solution. The solution was reacted for about twelve hours, while the temperature of the solution was slowly increased to about 25° C. (room temperature). A second product, i.e., a white solid material, was precipitated by drop-wise addition of the obtained solution to distilled water, which was then filtered. As a result, an inclusion complex including β-cyclodextrin, having tert-butyl carbonate group as a host and 1-adamantanecarboxylic acid as a guest, was obtained.

A structure of the inclusion complex was confirmed using a ¹H-nuclear magnetic resonance (¹H-NMR) spectrum. The ¹H-NMR spectrum was obtained using chloroform-d (CDCl₃) as a solvent and a 300 MHz NMR spectrometer. The ¹H-NMR spectrum showed chemical shifts (δ) of the final product at 1.45 (3H, s, methyl), 1.7 (12H, d, H from adamantane secondary carbon), 1.9 (4H, m, H from adamantane tertiary carbon), 3.8 (m, H from broad s, β-cyclodextrin), 4.8 (broad s, primary-OH), and 5.0 (broad s, secondary-OH).

### COMPARATIVE EXAMPLE 1

### Synthesis of a β-Cyclodextrin Derivative

Comparative Example 1 is disclosed in the related U.S. patent application identified above, entitled “Cyclodextrin Derivative, Photoresist Composition Including the Cyclodextrin Derivative and Method of Forming a Pattern Using the Photoresist Composition.”

About 14.8 g, i.e., 0.013 moles, of β-cyclodextrin was dissolved in about 20 mL of N,N-dimetylacetamide, and then 4-(dimethylamino)pyridine was added to the solution as a catalyst. While keeping the solution at 0° C., about 17.46 g, i.e., about 18.28 mL or about 0.080 moles, of di-tert-butyl dicarbonate was slowly added to the solution. The solution was reacted for about twelve hours while slowly increasing the temperature of the solution up to about 25° C. or room temperature. A white solid material was precipitated by drop-wise addition of the obtained solution to distilled water. A final product was filtered from the aqueous solution including the white solid material and dried. As a result, a β-cyclodextrin derivative including β-cyclodextrin, in which a tert-butyl carbonate group was combined, was obtained.

A structure of the final product was confirmed using a ¹H-nuclear magnetic resonance (¹H-NMR) spectrum. The ¹H-NMR spectrum was obtained using chloroform-d (CDCl₃) as a solvent and a 300 MHz NMR spectrometer. The ¹H-NMR spectrum showed chemical shifts (δ) of the final product at 1.45 (3H, S, methyl), 3.8 (m, H from β-cyclodextrin), 4.8 (broad s, primary-OH) and 5.0 (broad s, secondary-OH).

### EXAMPLE 2

### Preparation of a Photoresist Composition

Preparation of a photoresist composition was performed in a laboratory in which a far ultraviolet ray was blocked. About 111 parts by weight of the inclusion complex obtained in Example 1 and about 20 parts by weight of triphenylsulfonium triflate used as a photoacid generator were dissolved in about 887 parts by weight of propyleneglycol monomethyl ether acetate. The solution was then filtered using a membrane filter having a thickness of about 0.2 μm. As a result, a photoresist composition was obtained.

### COMPARATIVE EXAMPLE 2

### Preparation of a Photoresist Composition

Comparative Example 2 is disclosed in the related U.S. patent application identified above, entitled “Cyclodextrin Derivative, Photoresist Composition Including the Cyclodextrin Derivative and Method of Forming a Pattern Using the Photoresist Composition.”

A photoresist composition was prepared in a laboratory in which a far ultraviolet ray was blocked. About 111 parts by weight of the P-cyclodextrin derivative obtained in Comparative Example 1 and about 20 parts by weight of triphenylsulfonium triflate used as a photoacid generator were dissolved in about 887 parts by weight of propyleneglycol monomethyl ether acetate. The solution was then filtered using a membrane filter having a thickness of about 0.2 μm. As a result, a photoresist composition was obtained.

### COMPARATIVE EXAMPLE 3

### Preparation of a Photoresist Composition

About 111 parts by weight of polyhydroxystyrene and about 20 parts by weight of triphenylsulfonium triflate used as a photoacid generator were dissolved in about 887 parts by weight of propyleneglycol monomethyl ether acetate. The solution was then filtered using a membrane filter having a thickness of about 0.2 μm. As a result, a photoresist composition was obtained.

### Evaluation of Etching Resistances of Photoresist Patterns

The photoresist compositions prepared in Example 2 and Comparative Examples 2 and 3 were separately spin-coated on silicon wafers on which the silicon nitride film is formed, and then the silicon wafers were heated at a temperature of about 100° C. for about 90 seconds. As a result, photoresist films having a thickness of about 0.4 μm were formed on the silicon wafers. The photoresist films were partially exposed to an Hg—Xe laser, and then the photoresist films were thermally treated again at a temperature of about 110° C. for about 90 seconds.

Exposed portions of the photoresist films were removed from the photoresist films using about 2.38 percent by weight of a tetramethylammonium hydroxide developing solution. A rinse process and a dry process were then performed on the silicon wafers to remove residues of the developing solution and to complete photoresist patterns. A thickness of each of the photoresist patterns was about 3,000 Å.

Thereafter, etching rates and relative etching ratios of the photoresist patterns formed using the photoresist compositions obtained in Example 2 and Comparative Examples 2 to 3 were measured as shown in Table 2 by etching each of the photoresist patterns in an etching camber, which was set as shown in Table 1. The relative etching ratio is a dimensionless ratio of an etching amount of the photoresist pattern in Example 2 or Comparative Example 2 to an etching amount of the photoresist pattern in Comparative Example 3.

TABLE 1

| | |
|---|---|
| CF₄Flow Rate | 30 sccm |
| RF Power | 100 W |
| Pressure | 200 mTorr |

TABLE 2

| | Etching Rate (Å/sec) | Etching Ratio |
|---|---|---|
| Example 2 | 11.90 | 1.14 |
| Comparative Example 2 | 14.40 | 1.38 |
| Comparative Example 3 | 10.40 | 1.00 |

Referring to Table 2, the photoresist pattern in Example 2 has an etching rate similar to that of the photoresist pattern in Comparative Example 3. The photoresist pattern in Example 2 has an etching rate substantially lower than that of the photoresist pattern in Comparative Example 2, which does not include an adamantane derivative functioning as an etching resistance group. Accordingly, the photoresist pattern in Example 2 has an excellent etching resistance and may be used as an etching mask for forming a pattern on a semiconductor substrate.

The inclusion complex may not exhibit crystalline properties, which are generally characteristics of a low molecular weight compound, and may have amorphousness. Therefore, the inclusion complex may be applied to a photoresist composition suitable for spin-coating. The photoresist composition including the inclusion complex may have an enhanced etching resistance compared to a conventional photoresist composition including a low molecular weight resin, and thus a photoresist pattern formed using the photoresist composition may have an improved etching resistance in a process etching an underlying layer of the photoresist pattern. Accordingly, a photoresist pattern having an improved profile may be formed, and efficiency of a semiconductor device may be increased.

The foregoing is illustrative of the present invention and is not to be construed as limiting thereof. While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative. Accordingly, all such modifications are intended to be included within the scope of the present invention, as defined in the claims.

What is claimed is:

1. An inclusion complex for a photoresist comprising:
a β-cyclodextrin derivative as a host; and
an adamantane derivative as a guest.

2. The inclusion complex of claim 1, wherein the inclusion complex has a chemical structure represented by Formula (1), 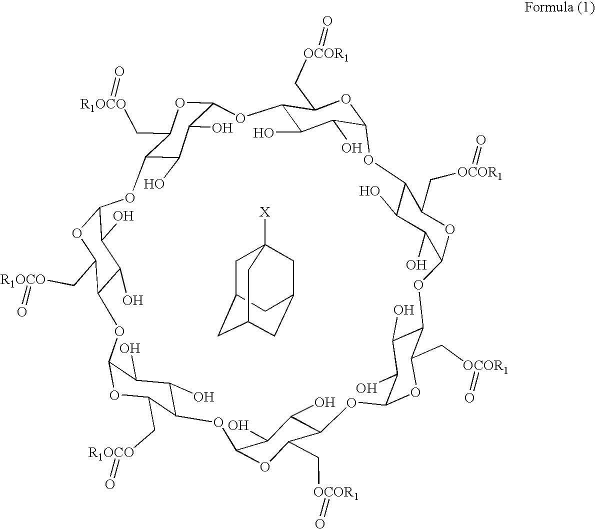
wherein R₁ represents an alkyl group comprising 1 to 10 carbon atoms, and X represents one of a carboxyl group or an alkyl group comprising 1 to 4 carbon atoms.

3. The inclusion complex of claim 1, wherein the β-cyclodextrin derivative is prepared by combining β-cyclodextrin with a tert-butyl carbonate group, and is represented by formula (2).

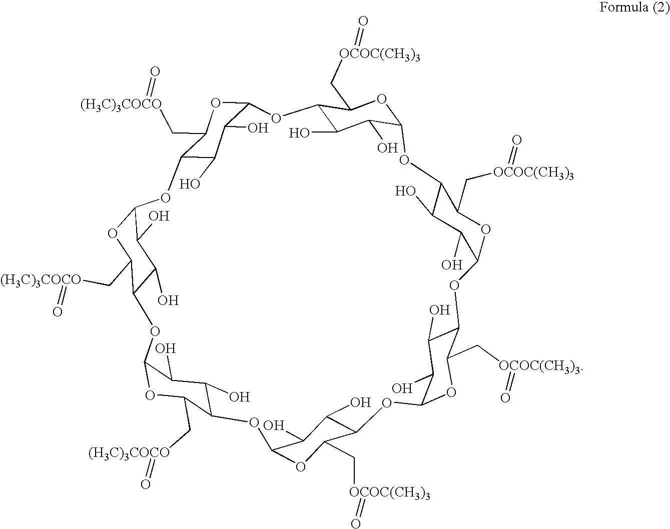

4. The inclusion complex of claim 1, wherein the adamantane derivative has a chemical structure represented by Formula (3), 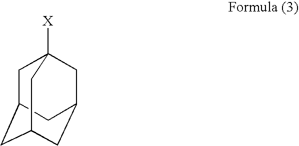
wherein X represents one of a carboxyl group or an alkyl group comprising 1 to 4 carbon atoms.

5. The inclusion complex of claim 1, wherein the inclusion complex is prepared by inserting the adamantane derivative into a cavity of β-cyclodextrin, and by reacting the β-cyclodextrin and the inserted adamantane derivative with a dialkyl dicarbonate.

6. A photoresist composition, comprising:
about 7 percent to about 14 percent by weight of an inclusion complex comprising a β-cyclodextrin derivative as a host and an adamantane derivative as a guest;
about 0.1 percent to about 0.5 percent by weight of a photoacid generator; and
a remainder of an organic solvent.

7. The photoresist composition of claim 6, wherein the inclusion complex has a chemical structure represented by Formula (1), 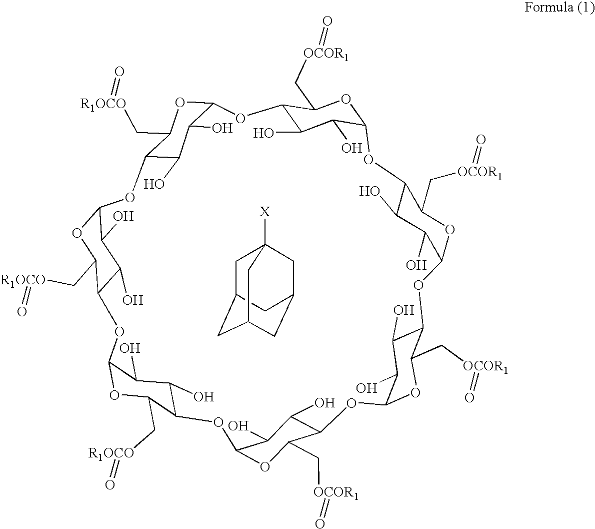
wherein R₁ represents an alkyl group comprising 1 to 10 carbon atoms, and X represents one of a carboxyl group or an alkyl group comprising 1 to 4 carbon atoms.

8. The photoresist composition of claim 6, wherein the β-cyclodextrin derivative is prepared by combining β-cyclodextrin with a tert-butyl carbonate, and is represented by Formula (2).

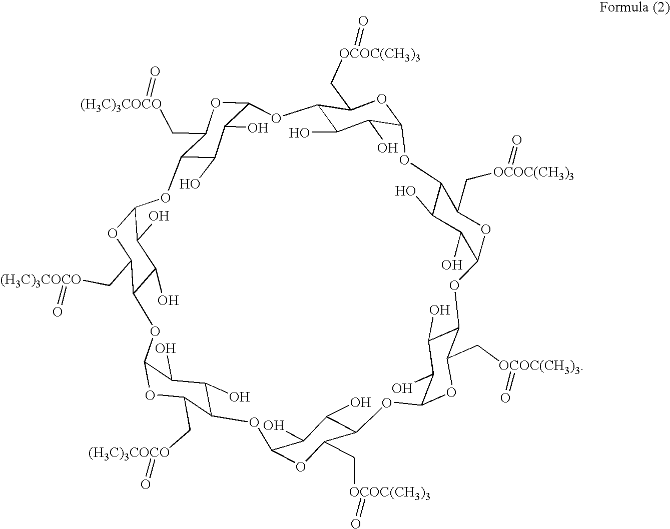

9. The photoresist composition of claim 6, wherein the adamantane derivative has a chemical structure represented by Formula (3), 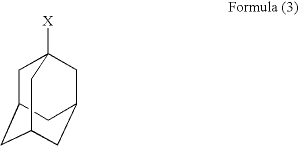
wherein X represents one of a carboxyl group or an alkyl group comprising I to 4 carbon atoms.

10. The photoresist composition of claim 6, wherein the photoacid generator comprises at least one selected from the group consisting of a triarylsulfonium salt, a diaryliodonium salt, a sulfonate and N-hydroxysuccinimide triflate.

11. The photoresist composition of claim 6, wherein the organic solvent comprises at least one selected from the group consisting of ethylene glycol monomethyl ether, ethylene glycol monoethyl ether, propylene glycol methyl ether, methyl cellosolve acetate, ethyl cellosolve acetate, diethylene glycol monomethyl ether, diethylene glycol monoethyl ether, propylene glycol methyl ether acetate, propylene glycol propylether acetate, diethylene glycol dimethylether, ethyl lactate, toluene, xylene, methyl ethyl ketone, cyclohexanone, 2-heptanone, 3-heptanone and 4-heptanone.

12. A method of forming a pattern on a substrate, the method comprising:
forming a photoresist film on an object layer by coating the object layer with a photoresist composition comprising about 7 percent to about 14 percent by weight of an inclusion complex having a chemical structure represented by Formula (1), about 0.1 percent to about 0.5 percent by weight of a photoacid generator, and a remainder of an organic solvent;
partially exposing the photoresist film to light by performing an exposure process;
developing the photoresist film using a developing solution to form a photoresist pattern on the object layer; and
partially etching the object layer using the photoresist pattern as an etching mask to form the pattern on the substrate, 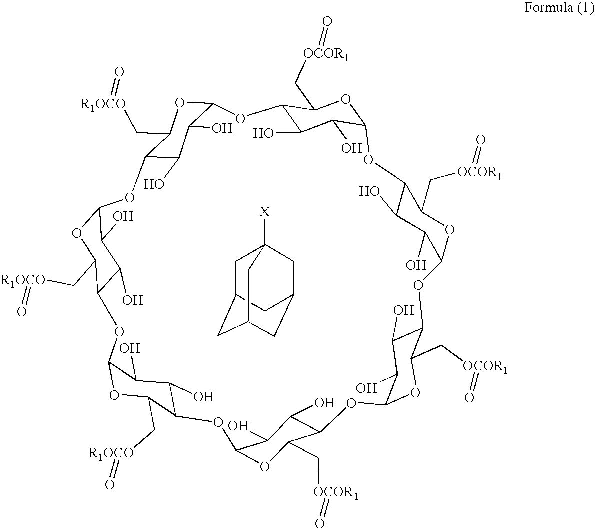
wherein R₁ represents an alkyl group having 1 to 10 carbon atoms, and X represents one of a carboxy group or an alkyl group comprising 1 to 4 carbon atoms.

13. The method of claim 12, further comprising:
baking the photoresist film at a temperature of about 110° C. to about 130° C. prior to developing the photoresist film.
